(19) United States
(12) Patent Application Publication
(10) Pub. No.: US 2025/0033953 A1
(43) Pub. Date: Jan. 30, 2025

(54) MULTI-DIRECTIONAL ACOUSTIC SENSOR DEVICES

(71) Applicant: Soundskrit Inc., Montreal (CA)

(72) Inventors: Sahil Gupta, Montreal (CA); Ravi Patel, Montreal (CA); Paul Ionescu, Laval (CA); Stephane Leahy, Montreal (CA)

(21) Appl. No.: 18/786,239

(22) Filed: Jul. 26, 2024

Related U.S. Application Data
(60) Provisional application No. 63/529,251, filed on Jul. 27, 2023.

(51) Int. Cl. B81B 7/00; H04R 1/40

(52) U.S. Cl. CPC B81B 7/0061; H04R 1/406; B81B 2201/0257; B81B 2203/0127; B81B 2203/0315; B81B 2203/0353; H04R 2201/003

(57) ABSTRACT

An acoustic sensor device comprises a package, a substrate disposed in the package or forming a part of the package, and a plurality of microelectromechanical system (MEMS) transducers supported by the substrate and packaged in the package. The plurality of sound ports configured to couple the plurality of MEMS transducers to an ambient environment of the acoustic sensor device. The plurality of sound ports are arranged in the package such that respective MEMS transducers, among the plurality of MEMS transducers, exhibit different directional pick-up patterns with respect to sound waves traveling in the ambient environment of the acoustic sensor device.

### CROSS-REFERENCES TO RELATED APPLICATIONS

This application claims the benefit of U.S. provisional application entitled “Multi-Directional Microphone,” filed Jul. 27, 2023, and assigned Ser. No. 63/529,251, the entire disclosure of which is hereby expressly incorporated by reference.

### BACKGROUND OF THE DISCLOSURE

### Field of the Disclosure

The disclosure relates generally to acoustic sensor devices that as microelectromechanical system (MEMS) microphones.

### Brief Description of Related Technology

A directional acoustic sensor device (e.g., a directional microphone) is an acoustic sensor device designed to have high sensitivity to sound travelling in one direction and low sensitivity to sound travelling in another direction. Such directionality allows the acoustic sensor to separate sound sources. A typical directional acoustic sensor device includes two sound ports, exposing each opposing side of a transducer, or membrane, to an ambient environment. The transducer, or membrane, is disposed in a package of the acoustic sensor device such that the transducer or membrane partitions the package into two air volumes, a front volume and a back volume. A first sound port formed in the package couples the front volume of air to the outside ambient environment at a first location. A second sound port formed in the package couples the back volume of air to the outside ambient environment at a second location spaced at some distance from the first location. As a sound wave travels past the acoustic sensor device, the sound wave creates a first local pressure at the location of the first sound port and a second local pressure at the location of the second sound port. The difference in the first pressure and second pressure exerts a force on the membrane and causes the membrane to vibrate. The vibrations of the membrane are then converted to an electrical signal through one of a variety of transduction mechanism such as capacitive, piezoelectric, optical, or piezoresistive readout.

A directional acoustic sensor device is typically configured to provide a directional output having a particular directionality pattern. For example, a dipole microphone is designed to have relatively higher sensitivity to sound emanating from the front and the back of the microphone and relatively lower sensitivity to sound emanating from the sides of the microphone. Thus, a typical acoustic sensor device provides a single directional output having directionality that depends on the orientation of the acoustic sensor device. If two directional outputs are desired in an acoustic system, two separate acoustic sensor devices may be integrated together, e.g., with different orientations, to provide the desired directionalities for the acoustic systems. Integrating two separate acoustic sensor devices in an acoustic system typically increases the size and the cost of the acoustic system.

### SUMMARY OF THE DISCLOSURE

In accordance with one aspect of the disclosure, an acoustic sensor device comprises a package, a substrate disposed in the package or forming a part of the package, and a plurality of microelectromechanical system (MEMS) transducers supported by the substrate and packaged in the package. The acoustic sensor device also includes a plurality of sound ports configured to couple the plurality of MEMS transducers to an ambient environment of the acoustic sensor device. The plurality of sound ports are arranged in the package such that respective MEMS transducers, among the plurality of MEMS transducers, exhibit different directional pick-up patterns with respect to sound waves traveling in the ambient environment of the acoustic sensor device.

In accordance with another aspect of the disclosure, an acoustic sensor device comprises a package, a substrate disposed in the package or forming a part of the package, and a plurality of transducers formed in one or more semiconductor dies supported by the substrate and packaged in the package. The acoustic sensor device also includes a plurality of sound ports configured to couple the plurality of transducers to an ambient environment of the acoustic sensor device. The plurality of sound ports are arranged in the package such that respective transducers, among the plurality of transducers, exhibit respective directional pick-up patterns that are orthogonal to each other.

In connection with any one of the aforementioned aspects, the acoustic sensor devices described herein may alternatively or additionally include or involve any suitable combination of one or more of the following aspects or features. The plurality of sound ports are arranged such that the plurality of MEMS transducers exhibit respective directional pick-up patterns that are orthogonal to each other. The plurality of sound ports are arranged in the package such that the plurality of MEMS transducers exhibit respective dipole patterns that are orthogonal to each other. At least one sound port, among the plurality of sound ports, comprises a mesh covering configured to cause at least one MEMS transducer, among the plurality of MEMS transducers, to exhibit a cardioid pick-up pattern with respect to sound waves traveling in the ambient environment of the acoustic sensor device. The acoustic sensor device further comprises an application specific integrated circuit (ASIC) configured to read out and process respective electrical signals generated by respective MEMS transducers among the plurality of MEMS transducers. The acoustic sensor device further comprises a lid attached to the substrate to encapsulate the plurality of MEMS transducers. The plurality of MEMS transducers includes a first MEMS transducer and a second MEMS transducer. The plurality of sound ports includes a first sound port configured to couple a first side of the first MEMS transducer to the ambient environment, a second sound port configured to couple a first side of the second MEMS transducer to the ambient environment, and a third sound port configured to couple a second side of the first MEMS transducer and a second side of the second MEMS transducer to the ambient environment. The first sound port and the third sound port are arranged in-plane along a first axis on the substrate and spaced apart from each other along the first axis on the substrate. The second sound port and the third sound port are arranged in-plane along a second axis and spaced apart from each other along the second axis on the substrate. The first axis and the second axis are orthogonal to each other. The first sound port, the second sound port, and the third sound port are formed in the substrate of the package. The first MEMS transducer comprises a first sensing element suspended over a first cavity, wherein the first MEMS transducer is arranged in the package such that the first cavity is placed over the first sound port formed in the substrate. The second MEMS transducer comprises a second sending element suspended over a second cavity, wherein the second MEMS transducer is arranged in the package such that the second cavity is placed over the second sound port formed in the substrate. At least one of the first sound port and the second sound port includes a mesh covering. A first sound port among the plurality of sound ports is configured to be coupled via an acoustic channel to a further sound port formed in an end product device configured to use the acoustic sensor device. The acoustic channel is arranged such that a distance between the further sound port formed in the end product device and a second sound port among the plurality of sound ports of the acoustic sensor device is larger than a distance between the first sound port and the second sound port of the acoustic sensor device. The plurality of sound ports are arranged in the package such that the plurality of transducers exhibit respective dipole pick-up patterns that are orthogonal to each other. The plurality of transducers comprise a plurality of microelectromechanical system (MEMS) transducers. The acoustic sensor device of claim 15 further comprises an application specific integrated circuit (ASIC) configured to read out and process respective electrical signals generated by respective transducers among the plurality of transducers. The acoustic sensor device further comprises a lid attached to the substrate to encapsulate the plurality of transducers. A particular sound port among the plurality of sound ports is shared by multiple transducers among the plurality of transducers such that the particular sound ports couples the multiple transducers to the ambient environment.

### BRIEF DESCRIPTION OF THE DRAWING FIGURES

For a more complete understanding of the disclosure, reference should be made to the following detailed description and accompanying drawing figures, in which like reference numerals identify like elements in the figures.

FIG. 1A depicts a top view of a multi-directional MEMS microphone, in accordance with an example.

FIG. 1B depicts a bottom view of the MEMS microphone of FIG. 1A mounted on a printed circuit board, in accordance with an example.

FIG. 2A depicts a top perspective view of an acoustic sensor device, in accordance with an example.

FIG. 2B depicts a bottom perspective view of the acoustic sensor device of FIG. 2A, in accordance with an example.

FIG. 2C shows a cross-sectional, schematic view of the acoustic sensor device of FIG. 2A looking in a first direction, in accordance with an example.

FIG. 2D shows a cross-sectional, schematic view of acoustic sensor device of FIG. 2A looking in second direction, in accordance with an example.

FIG. 3A depicts a bottom perspective view of an acoustic sensor device, in accordance with an example.

FIG. 3B depicts a top perspective view of the acoustic sensor device of FIG. 3A, in accordance with an example.

FIG. 3C shows a cross-sectional, schematic of the acoustic sensor device of FIG. 3A looking in a first direction, in accordance with an example.

FIG. 3D shows a cross-sectional, schematic of the acoustic sensor device of FIG. 3A looking in a second direction, in accordance with an example.

The embodiments of the disclosed devices may assume various forms. Specific embodiments are illustrated in the drawing and hereafter described with the understanding that the disclosure is intended to be illustrative. The disclosure is not intended to limit the invention to the specific embodiments described and illustrated herein.

### DETAILED DESCRIPTION OF THE DISCLOSURE

Acoustic sensor devices (e.g., microphones) with a packaging architecture to accommodate multiple transducers within a single package are described. In various examples, the packaging architecture of the disclosed acoustic sensor devices supports the realization of a multi-directional acoustic sensor device (e.g., a multi-directional microphone) in a single package that provides multiple directional audio outputs. In an aspect, an acoustic sensor device includes a package and a substrate (e.g., a printed circuit board) disposed in the package or forming a part of the package. The acoustic sensor device also includes a plurality of transducers (e.g., MEMS transducers) supported by the substrate and packaged in the package. The plurality of transducers includes, for example, a first transducer and a second transducer supported by the substrate and packaged in the package. The acoustic sensor device further includes a plurality of sound ports configured to couple the plurality of transducers to an ambient environment of the acoustic sensor device. In an example, the plurality of sound ports are arranged in the package such that respective transducers, among the plurality of transducers, exhibit different directional pick-up patterns with respect to sound waves traveling in the ambient environment of the acoustic sensor device. For example, the plurality of sound ports are arranged such that the first transducer and the second transducer exhibit directional pick-up patterns (e.g., dipoles) that are orthogonal to each other. The acoustic sensor device may thus pick up sound waves emanating from directions along two axis that are perpendicular to each other (e.g., the front and the back of the acoustic sensor device and the left and the right of the acoustic sensor device) while rejecting or attenuating sound waves traveling in directions other than along the two perpendicular axes. In other examples, the plurality of sound ports may be arranged in the package such that the plurality of transducers exhibit other directional pick-up patterns, such as a dipole pattern and a cardioid pattern, or two cardioid patterns oriented in different directions, for example

In some cases, the packaging architecture of the disclosed acoustic sensor devices includes a sound port shared by more than one of the transducers disposed within the single package. Additional or alternative aspects of the disclosed acoustic sensor devices may be shared by the multiple transducers. For instance, because multiple transducers are disposed in the same package, the transducers may share one or more components, such as a single microphone lid, a single printed circuit board (PCB), and/or a single application-specific circuit (ASIC). Such component sharing reduces the total solution cost.

Shared ports at the transducer level within the single package and/or other aspects of the disclosed devices support the realization of an acoustic sensor device (e.g., a microphone) with multiple directional outputs in a smaller form factor than that presented by, for instance, an arrangement with separately packaged directional microphones oriented in different directions. The form factor achieved by the packaging architecture may also be smaller than arrangements in which separate directional microphones share a port through an external gasket or a housing of an end product device in which the microphones are integrated. A smaller total footprint may thus be achieved, which is useful because, for instance, the smaller footprint may provide the flexibility to integrate the disclosed microphone device into a variety of products (e.g., with different form factors).

As described herein, in an example in which the acoustic sensor device includes two transducers, one side of each transducer shares a port. In other words, the shared port is coupled with, or connected to, one side of each transducer. The other side of each transducer is coupled with, or connected to, a respective unshared port, in an example.

In some cases, the transducer (or membrane thereof) is disposed at (or closer to) the unshared port rather than the shared port associated with that membrane or transducer. However, the positioning of the transducers (or membranes thereof) may vary. For instance, each transducer may be disposed at or near a center point between the pair of ports to which the transducer is coupled or connected.

Although described in connection with MEMS transducers having perforated cantilever plate diaphragms, the packaging architecture of the disclosed microphones may be used in connection with a wide variety of transducers and microphones. Any suitable type of pressure-sensing transducer may be used. For instance, the disclosed transducers may use a nonporous or non-cantilever based design.

The disclosed multi-directional sensor devices are not limited to packaging architectures having a single shared port. The disclosed multi-directional sensor devices are also not limited to architectures having two transducers. In some examples, additional shared ports may be included to accommodate additional transducers.

The disclosed multi-directional sensor devices may be useful in a wide variety of microphone applications and contexts, including, for instance, various consumer devices such as smartphones, laptops, and earbuds that include or are otherwise equipped with microphones. Further, although generally described in connection with microphones, the disclosed multi-directional sensor devices may be used in other applications and contexts. For instance, the disclosed multi-directional sensor devices are useful in connection with accelerometers, gyroscopes, inertial sensors, pressure sensors, gas sensors, etc. The disclosed multi-directional sensor devices are described in the context of excitation by sound waves. However, alternative or additional stimuli may excite the transducers of the disclosed sensor devices in other contexts.

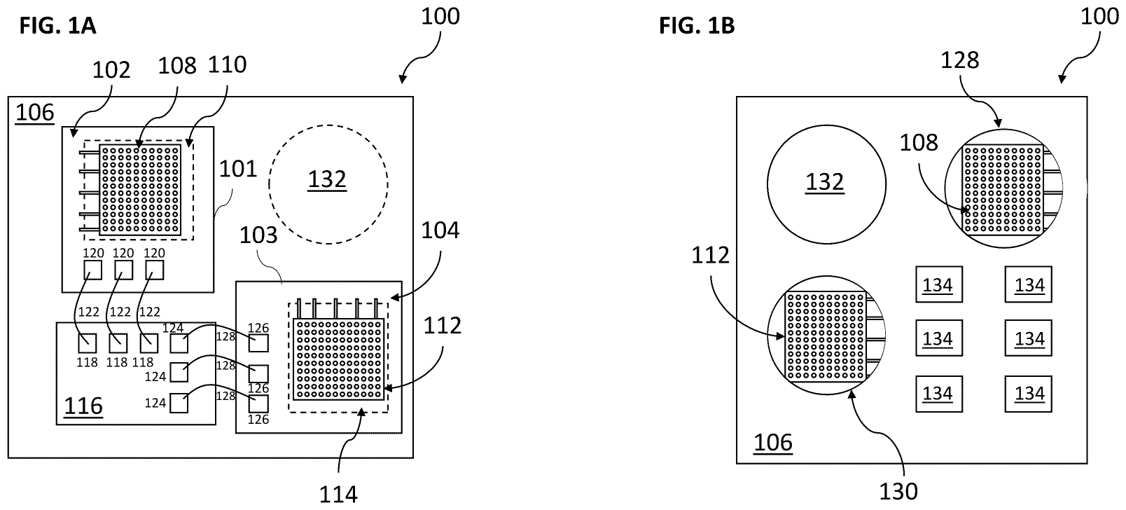

FIG. 1A depicts a top view of a multi-directional acoustic sensor device (e.g., MEMS microphone) 100 in accordance with one example. The acoustic sensor device 100 includes a plurality of transducers, including at least a first transducer 101 and a second transducer 103. Each of the first transducer 101 and the second transducer 103 may be a MEMS transducer, for example. The first transducer 101 is sometimes referred to herein as a “first MEMS transducer 101” and the second transducer 103 is sometimes referred to herein as a “second MEMS transducer 103” for illustrative purposes. In other examples, however, the first transducer 101 and/or the second MEMS transducer 103 may comprise a suitable transducer other than a MEMS transducer. Although for illustrative purposes the acoustic sensor device 100 is generally described herein as including two transducers, in other examples the acoustic sensor device 100 may include a greater number (e.g., three, four, etc.) of transducers.

The first MEMS transducer 101 and second MEMS transducer 103 are mounted on or otherwise supported by a printed circuit board (PCB) or other substrate 106 (sometimes referred to herein as simply “PCB 106”) using an adhesive layer, die attach, glue, or any other method known to those having ordinary skill in the art. The first MEMS transducer 101 and the second MEMS transducer 103 may be formed in one or more substrates, such as one or more semiconductor dies. In an example, the first MEMS transducer 101 is patterned and etched in a first substrate (e.g., a first semiconductor die) 102 and includes a sensing element (e.g., a diaphragm) 108 suspended over a cavity 110 in the first substrate 102. The cavity in the first substrate 102 may be formed via deep reactive ion etching, for example. The second MEMS transducer 103 is patterned and etched in a second substrate (e.g., a second semiconductor die) 104 and includes a sensing element (e.g., a diaphragm) 108 suspended over a cavity 114 in the second substrate 104. The cavity 114 in the second substrate 104 may be formed via deep reactive ion etching, for example. In another example, the first MEMS transducer 101 and the second MEMS transducer 103 may be formed in a single semiconductor die.

The sensing elements 108 and 112 are configured such that they vibrate when exposed to an external stimulus such as an acoustic wave. The sensing elements 108 and 112 may be cantilevers that are anchored to at least one edge of their respective substrates 102 and 104 and are free to move on at least one side that is not anchored to the substrate 102, 104. The sensing elements 108 and 112 may be configured as, or otherwise include, one or multiple porous plates. In other cases, one or both of the sensing elements 108, 112 may be configured as, or may otherwise include, an array of beams with air gaps between them. In other cases, one or both of the sensing elements 108, 112 may comprise a relatively nonporous plate. The MEMS transducers 101, 103 may be constructed such that they are relatively thin. For example, each of the MEMS transducers 101, 103 may be less than 2 μm in thickness. The MEMS transducers 101, 103 may be further configured as capacitive sensors that transduce their mechanical motion into an electrical signal.

The acoustic sensor device 100 may also include an application specific circuit (ASIC) 116. The ASIC 116 may be mounted on or otherwise supported by the PCB 106 through an adhesive layer, die attach, glue, or any other method known to those having ordinary skill in the art. The ASIC 116 may include one or more bond pads 118 that may be electrically connected to bond pads 120 of the first MEMS transducer 101 through wirebonds 122. The ASIC 116 may also include one or more bond pads 124 and that may be electrically connected to bond pads 126 of the second MEMS transducer 103 through wirebonds 128. The ASIC 116 may be further connected to the PCB 106 through wirebonds between additional bond pads (not shown). In some instances, the ASIC 116 may include two or more separate ASICs, e.g., with a first ASIC connected to the first MEMS transducer 101 and a second ASIC connected to the second MEMS transducer 103.

The ASIC 116 may be configured to read out respective electrical signals generated by the first MEMS transducer 101 and the second MEMS transducer 103 and amplify the signals. In some examples, the ASIC 116 may provide one or more bias voltages to the first MEMS transducer 101 and/or the second MEMS transducer 103. The output of the ASIC 116 may be transmitted to an external processor through connections between the external processor and PCB 106.

FIG. 1B depicts a bottom view of the acoustic sensor device 100, according to an example. As illustrated in FIG. 1B, the PCB 106 includes a first hole, or sound port, 128 over which the sensing element 108 of the first MEMS transducer 101 is suspended. The sound port 128 couples the ambient air to the bottom side of the sensing element 108 of the first MEMS transducer 101. The PCB 106 includes a second hole, or sound port, 130 over which the sensing element 112 of the second MEMS transducer 103 is suspended. The sound port 130 couples the ambient air to the bottom side of the sensing element 112 of the second MEMS transducer 103. Additionally, the PCB 106 includes a third hole, or sound port, 132 over which there is no MEMS transducer suspended. The sound port 132 serves to couple the ambient air to the top side of both of the sensing element 108 of the first MEMS transducers 101 and the sensing element 112 of the second MEMS transducer 103. In another example, respective different sound ports may be provided to couple the top side of the first MEMS transducers 101 and the top side of the second MEMS transducers 103 to the ambient environment.

On the bottom of the PCB 106 are one or more electrical pads 134. In some examples the pads 134 may be soldered on to an external PCB (not shown) and connect the ASIC 116 to external electrical components. The sound ports 128, 130, and 132 may have a circular, conical, elliptical, rectangular, hexagonal, or any other geometric profile. As described in more detail below, the sound ports 128, 130, and 132 may be arranged in the PCB 106 such that the first MEMS transducer 101 and the second MEMS transducer 103 exhibit different directional pick-up patterns with respect to sound waves traveling in the ambient environment around the acoustic sensor device 100. For example, the sound ports 128, 130, and 132 may be arranged in the PCB 106 such that the first MEMS transducer 101 and the second MEMS transducer 103 exhibit dipole pick-up patterns that are orthogonal to each other. It is noted that although the acoustic sensor device 100 is generally described herein in as including two transducers and three sound ports, the present disclosure is not so limited. In other examples, the acoustic sensor device 100 may include additional transducers and additional sound ports in the package of the acoustic sensor device 100. For example, the acoustic sensor device 100 may include three transducers packaged in the package of the acoustic sensor device 100. In an example, sound ports of the acoustic sensor device 100 may be arranged in the package of the acoustic sensor device such that respective ones of the three transducers exhibit different directional pick-up patterns with respect to direction of travel of sound waves in the ambient environment around the acoustic sensor device 100, such as dipole patterns that are orthogonal to one another in three-dimensional (3D) space. In other examples, other suitable numbers of transducers and/or other suitable directional pick-up patterns may be provided.

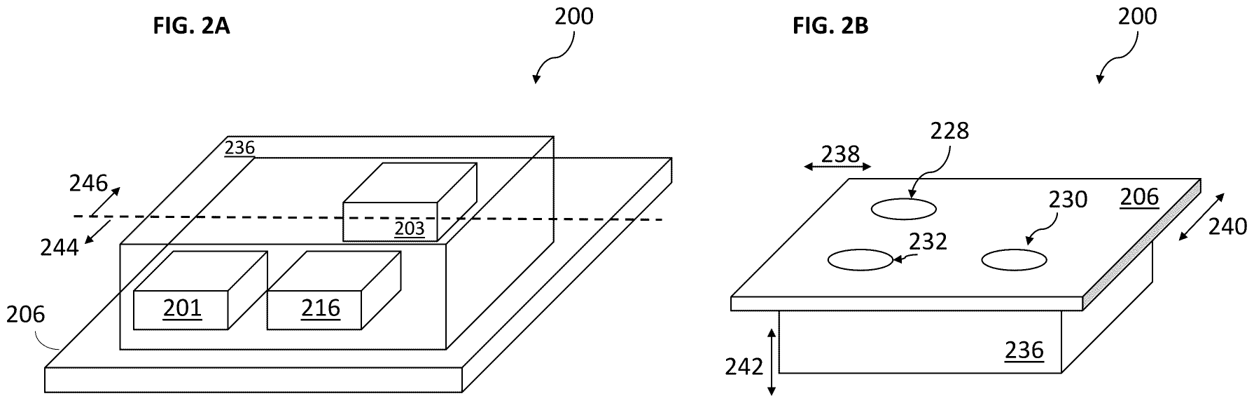

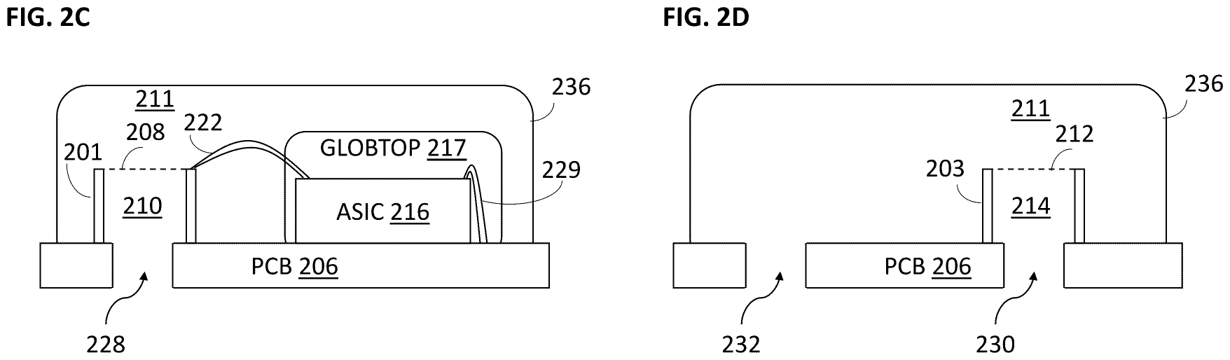

FIG. 2A depicts a top perspective view of an acoustic sensor device 200 in accordance with one example. The acoustic sensor device 200 may be or include a microphone, for example. In an example, the acoustic sensor device 200 corresponds to the acoustic device 100 of FIG. 1. The acoustic sensor device 200 includes like-numbered elements with the acoustic sensor device 100 of FIG. 1 that are not discussed in detail below for the purpose of brevity. The acoustic sensor device 200 includes a first transducer (e.g., MEMS transducer) 201, a second transducer (e.g., MEMS transducer) 203, and an ASIC 216 mounted on a PCB or other substrate 206 (sometimes referred to herein as simply “PCB 206”). The acoustic sensor device 200 also includes a lid 236 that may be attached to the PCB 206 and may encapsulate the first MEMS transducer 201, the second MEMS transducer 203, and the ASIC 216 mounted on the PCB 206.

FIG. 2B depicts a bottom perspective view of the acoustic sensor device 200. A first sound port 228, second sound port 230, and third sound port 232 are defined in the PCB 206 and couple the MEMS transducers 201 and 203 to the ambient air. The first MEMS transducer 201 is mounted with its cavity above the first sound port 228 and the second MEMS transducer 203 is mounted with its cavity above the second sound port 230.

As an acoustic wave, or sound, travels in direction 238, it hits sound ports 228 and 232 at the same time. This creates a similar pressure on the top side and bottom side of the first MEMS transducer 201. As a result, the first MEMS transducer 201 does not generate a signal for sound waves arriving along direction 238. However, when travelling along direction 238, an acoustic wave arrives at sound ports 232 and 230 at different times. As a result, this causes a difference in pressure between the top side and bottom side of the second MEMS transducer 203. Thus, the second MEMS transducer 203 generates a signal for sound waves arriving along direction 238.

As an acoustic wave, or sound, travels in direction 240, it hits sound ports 232 and 230 at the same time. This creates a similar pressure on the top side and bottom side of the second MEMS transducer 203. As a result, the second MEMS transducer 203 does not generate a signal for sound waves arriving along direction 240. However, when travelling along direction 240, an acoustic wave arrives at sound ports 228 and 232 at different times. As a result, this causes a difference in pressure between the top side and bottom side of the first MEMS transducer 201. Thus, the first MEMS transducer 201 generates a signal for sound waves arriving along direction 240.

As an acoustic wave, or sound, travels in direction 242, it hits sound ports 228, 230, and 232 at the same time. This creates a similar pressure on the top side and bottom side of both of the first MEMS transducer 201 and the second MEMS transducer 203. As a result, neither the first MEMS transducer 201 nor the second MEMS transducer 203 generates a signal for sound waves arriving along direction 242.

The acoustic sensor device 200 is said to be multi-directional because it includes two MEMS transducers exhibiting different directional pick-up patterns or responses. The first MEMS transducer 201 only outputs a signal, or is sensitive, to sound travelling along direction 238, while the second MEMS transducer 203 only outputs a signal, or is sensitive, to sound travelling along direction 240. The ASIC 216 may be configured to output a first signal and a second signal corresponding to the signal sensed by the first MEMS transducer 201 and the second MEMS transducer 203, respectively. In some instances, the sound ports 228, 230, and 232 may be oriented such that the directions of sensitivity of the first MEMS transducer 201 and the second MEMS transducer 203 are orthogonal, or perpendicular, to one another. In some instances, each of the first MEMS transducer 201 and/or the second MEMS transducer 203 may exhibit a dipole directionality. In other instances, the first MEMS transducer 201 and/or the second MEMS transducer 203 may exhibit directionality other than a dipole directionality. For example, one or more of the sound ports 228, 230, and/or 232 may be coupled to an acoustic mesh (e.g., a mesh covering) that adds acoustic resistance and converts the directional pattern of one or both of the first MEMS transducer 201 and/or the second MEMS transducer 203 to a cardioid-like pattern.

The lid 236 may be constructed such that the volume of air encapsulated by the lid 236 is sufficiently small so that the Helmholtz resonance of the package is near or above the audio spectrum (e.g., greater than 20 kHz).

FIG. 2C shows a cross-sectional, schematic view of the acoustic sensor device 200 looking in direction 244 (FIG. 2A). The first MEMS transducer 201 of the acoustic sensor device 200 is attached to or otherwise supported by the PCB 206. The PCB 206 may be or include a printed circuit board with one or multiple layers. The ASIC 216 may be mounted on or otherwise supported by the PCB 206 and may be covered by a protective gloptop 217. The ASIC 216 may be configured to read out the electrical signal from the first MEMS transducer 201. The ASIC 216 may be electrically connected to conductive traces on the PCB 206 by wire bonds 229. Both the first MEMS transducer 201 and the ASIC 216 may be encapsulated by the lid or other enclosure 236. The lid 236 may be made of a metal material. The first MEMS transducer 201 and the ASIC 216 may be electrically connected by wire bonds 222, either to each other, or directly to the PCB 206. The first MEMS transducer 201, the ASIC 216, and the lid 236 may also be attached using other methods known to those having ordinary skill in the art. For instance, the first MEMS transducer 201 may be attached to the PCB 206 using flip chip technology. The first sound port 228 may be embedded or otherwise defined in the PCB 206. The first MEMS transducer 201 includes a sensing element 208 suspended over a cavity 210. The sound port 228 couples the ambient air to the air in cavity 210 and thus the bottom side of the sensing element 208 of the first MEMS transducer 201. The top side of the sensing element 208 of the first MEMS transducer 201 is coupled to an air volume 211 encapsulated under the lid 236. Sound port 230 couples the ambient air to the air volume 211 and thus the top side of the sensing element 208 of the first MEMS transducer 201.

FIG. 2D shows a cross-sectional, schematic view of acoustic sensor device 200 looking in direction 246 (FIG. 2A). The device 200 includes the second MEMS transducer 203 attached to or otherwise supported by the PCB 206. The ASIC 216 shown in FIG. 2C is also electrically connected to the second MEMS transducer 203 by wirebonds (not shown). The second MEMS transducer 203 is also encapsulated by the lid or other enclosure 236. A second sound port 230 and third sound port 232 are embedded or otherwise defined in the PCB 206. The second MEMS transducer 203 includes a sensing element 212 suspended over a cavity 214. The sound port 232 couples the ambient air to the air in cavity 214 and thus the bottom side of the sensing element 212 of the second MEMS transducer 203. The top side of the sensing element 212 of the MEMS transducer 203 is coupled to the air volume 211 encapsulated under the lid 236. Sound port 230 couples the ambient air to the air volume 211 and thus the top side of the sensing element 212 of the MEMS transducer 203.

In FIGS. 2A-D, the sensitivity of the first MEMS transducer 201 may be dependent on the spacing between sound port 228 and 232. The larger the spacing between sound port 228 and 232, the larger the sensitivity of the first MEMS transducer 201 to external acoustic waves may be. Similarly, the sensitivity of the second MEMS transducer 203 may be dependent on the spacing between sound port 230 and 232. In some instances, it may be advantageous to increase the spacing between the sound ports 228, 230, and 232 when integrating the acoustic sensor device 200 into a product device (e.g., a laptop).

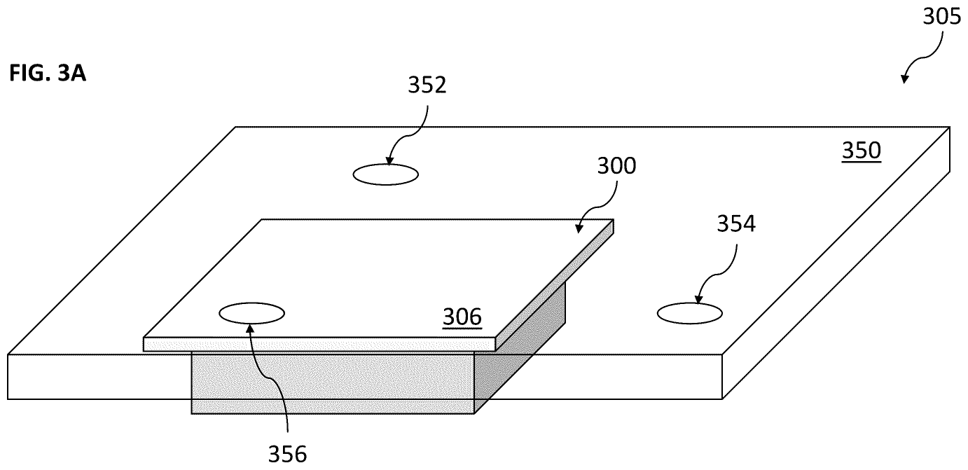

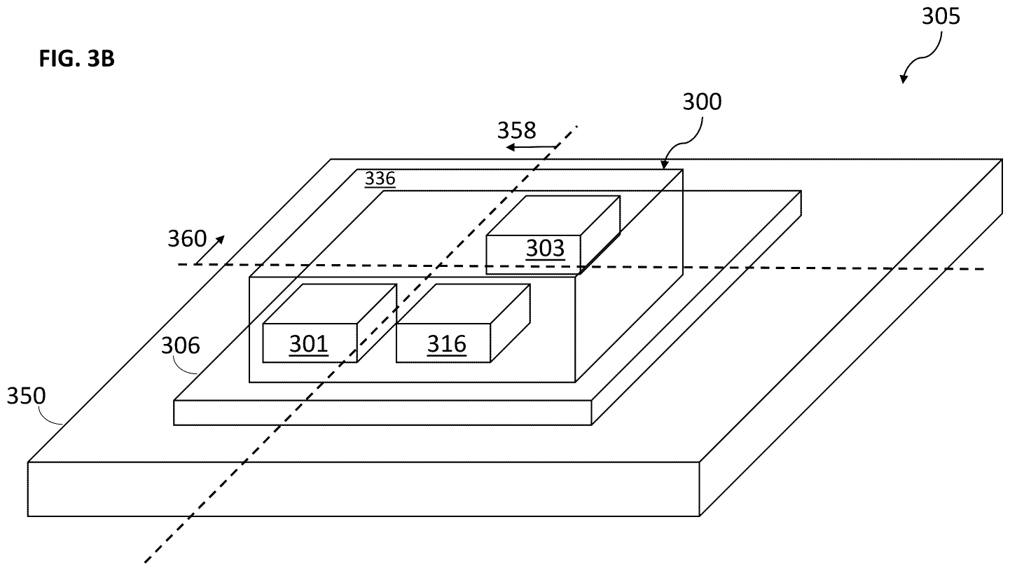

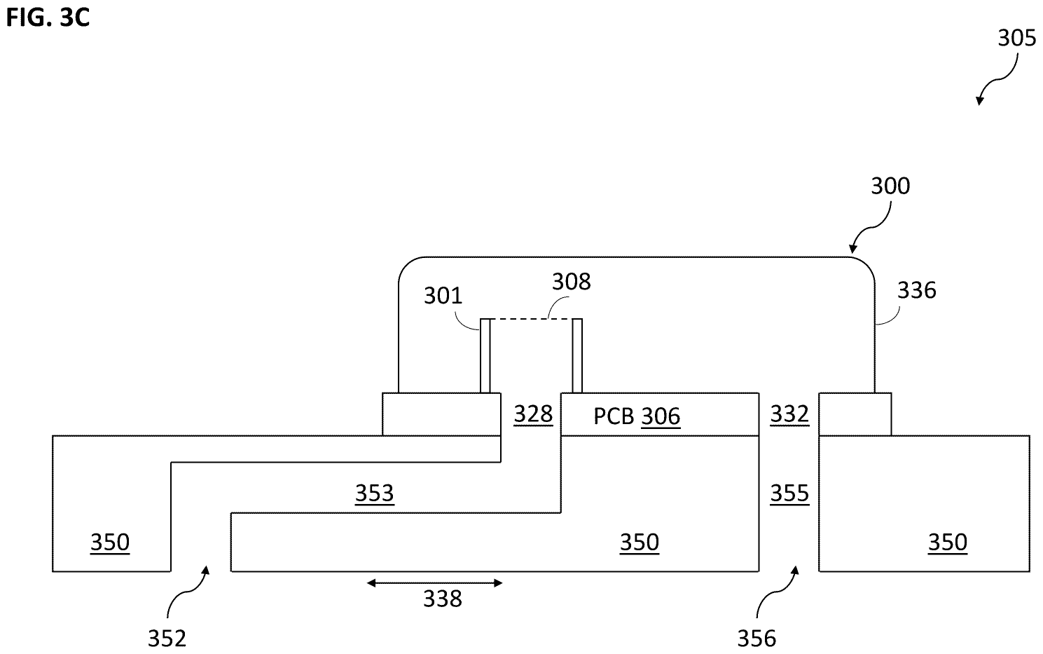

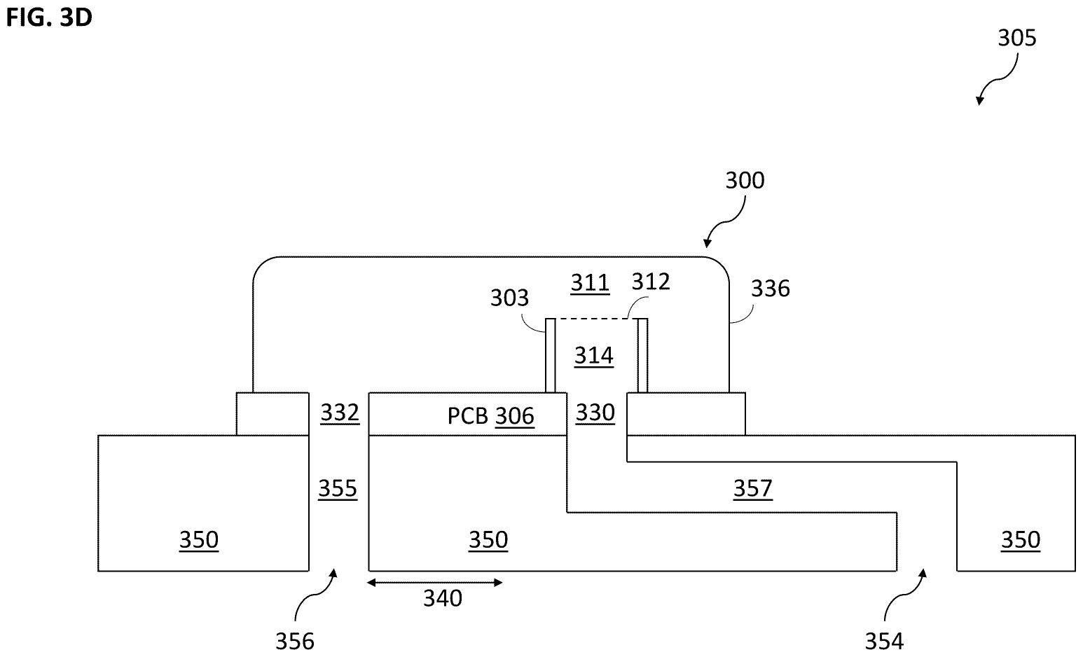

FIG. 3A depicts a bottom perspective view of an acoustic sensor device 300 in accordance with one example. The acoustic sensor device 300 is generally the same as the acoustic device 200 of FIG. 2 and includes like-numbered elements with the acoustic sensor device 200 of FIG. 2 that are not discussed in detail below for the purpose of brevity. The acoustic sensor device 300 is mounted onto, or integrated inside, a product housing or enclosure of an end product device 305 in accordance with one example. The acoustic sensor device 300 includes a PCB or other substrate 306 (sometimes referred to herein as simply “PCB 306”), which is mounted or otherwise supported by another substrate 350. The substrate 350 may be or include a further printed circuit board, or flexible printed circuit board, of the end product device 305. In some examples, the substrate 350 may include a printed circuit board and the product housing of the end product device 305. In some instances, the product housing may be composed of, or otherwise include, a plastic, metal, some other material suitable for product enclosures, or a combination thereof. Embedded in the enclosure and/or substrate 350 is a first sound port 352, a second sound port 354, and third sound port 356. The sound ports 352, 354, and 356 may couple to three sound ports embedded into or otherwise defined in the PCB 306 of the acoustic sensor device 300. However, in some instances, the sound ports 352, 354, and 356, may have a larger spacing than the sound ports embedded in the acoustic sensor PCB 306 to which they are coupled.

FIG. 3B depicts a top perspective view of the acoustic sensor device 300. The acoustic sensor device 300 is mounted onto, or integrated inside, a product housing or enclosure of the end product device 305 as described above in accordance with one example. The acoustic sensor device 300 includes a first MEMS transducer 301, a second MEMS transducer 303, and an ASIC 316 that are mounted onto the PCB 306 and encapsulated by a lid 336. The PCB 306 is mounted on or otherwise supported by the substrate 350, which may be the PCB of the end product device 305 as described above. In some examples, the substrate 350 may include a printed circuit board and the product housing.

FIG. 3C shows a cross-sectional, schematic of the acoustic sensor device 300 looking in direction 358 (FIG. 3B). The acoustic sensor device 300 includes the first MEMS transducer 301 attached to or otherwise supported by the PCB 306 and encapsulated by the lid 336. Embedded in the PCB 306 is a first sound port 328 and a third sound port 332. The PCB 306 is further supported by the PCB 350 of the end product device 305. The PCB 350 has a first sound port 352 and a third sound port 356. The sound port 352 is coupled to the sound port 328 through an acoustic channel 353, and thus couples the ambient air to the bottom side of a sensing element 308 of the first MEMS transducer 301. The sound port 356 is coupled to the sound port 330 through an acoustic channel 355 and thus couples the ambient air to the top side of the sensing element 308 of the first MEMS transducer 301. The acoustic channel 353 may be bent or otherwise arranged to move the sound port 352 away from the sound port 328, in a direction away from the location of the sound port 332. By using the bent or otherwise arranged acoustic channel 353 in such manner, the distance between the sound ports 352 and 356 in the end product device 305 is increased relative to the distance between the sound ports 328 and 332 in the acoustic sensor device 300. As sound travels along the direction 338, the bottom and top sides of the first MEMS transducer 301 are exposed to the pressure seen at sound ports 352 and 356, respectively. The increased spacing between the sound ports 352 and 356 results in an increase in sensitivity of the first MEMS transducer 301, in at least some examples. In some examples, PCB 350 may instead be the combination of a PCB of the end product device 305 and the surrounding enclosure (i.e., plastic, metal, or any other material suitable for product enclosures). Thus, the bent or otherwise arranged acoustic channel 353 may be built entirely in the PCB of the end product device 305, the outside enclosure, or a combination of both.

FIG. 3D shows a cross-sectional, schematic view of the acoustic sensor device 300 looking in direction 360 (FIG. 3B). The acoustic sensor device 300 includes the second MEMS transducer 303 attached to or otherwise supported by the PCB 306 and encapsulated by the lid 336. Embedded or defined in the PCB 306 is a second sound port 330 and a third sound port 332. The PCB 306 is further supported by the PCB 350 of the end product device 305. The PCB 350 has a second sound port 354 and a second third port 356. The sound port 354 is coupled to the sound port 330 through an acoustic channel 357, and thus couples the ambient air to the bottom side of a sensing element 312 of the second MEMS transducer 303. The sound port 356 is coupled to the sound port 332 through an acoustic channel 355 and thus couples the ambient air to the top side of the sensing element 312 of the second MEMS transducer 303. The acoustic channel 357 may be bent or otherwise arranged to move the sound port 354 away from the sound port 330, in a direction away from the location of the sound port 332. By using a bent or otherwise arranged acoustic channel 357 in such manner, the distance between the sound ports 354 and 356 in the end product device 305 is increased relative to the distance between the sound ports 330 and 332 in the acoustic sensor device 300. As sound travels along the direction 340, the bottom and top sides of the second MEMS transducer 303 are exposed to the pressure seen at sound port 354 and 356 respectively. The increased spacing between the sound ports 354 and 356 results in an increase in sensitivity of the second MEMS transducer 303, in at least some examples. In some examples, PCB 350 may instead be the combination of a PCB of the end product device 305 and the surrounding enclosure (i.e., plastic, metal, or any other material suitable for product enclosures). Thus, the bent or otherwise arranged acoustic channel 357 may be built entirely in the PCB of the end product device 305, the outside enclosure, or a combination of both.

Described above are a number of examples of acoustic sensor devices equipped with a plurality of transducers and a plurality of sound ports that are arranged in a package of the acoustic sensor device such that respective ones of the transducers exhibit different directional pick-up patterns or responses with respect to direction of travel of sound waves in an ambient environment around the acoustic sensor device. The acoustic sensor devices may thus provide multiple directional outputs. In an example, the plurality of transducer may include at least a first transducer and a second transducer, and the plurality of sound ports may include at least a first sound port configured to couple a first side of the first transducer to the ambient environment and a second sound port configured to couple a first side of the second transducer to the ambient environment. The plurality of sound ports may additionally include a third sound port configured to couple a second side of the first transducer and a second side of the second transducer to the ambient environment. In this example, the third sound port is a shared sound port that is used to couple the second side of both the first transducer and the second transducer to the ambient environment. In another example, the plurality of sound ports may include respective different sound ports configured to couple the second side of the first transducer and the second side of the second transducer to the ambient environment. In various examples, the plurality of sound ports may be arranged in the package such that the first transducer and the second transducer exhibit different directional patterns with respect to direction of travel of sound waves in the ambient environment. As just an example the plurality of sound ports may be arranged such that the first transducer and the second transducer exhibit dipole pick-up patterns that are orthogonal to each other. In other examples, other directional pick-up patterns exhibited by the first transducer and the second transducer may be provided. For example, one or more of the sound ports may be coupled to an acoustic mesh that adds acoustic resistance and converts the pick-up pattern of one or both of the first transducers and/or the second transducer to a cardioid-like pattern.

Although examples of acoustic sensor devices are generally described herein in as including two transducers and three sound ports, the present disclosure is not so limited. In other examples, the acoustic sensor devices may include additional transducers and additional sound ports in a package of the acoustic sensor device. For example, an acoustic sensor device may include three transducers packaged in a package of the acoustic sensor device. In an example, sound ports of the acoustic sensor device may be arranged in the package of the acoustic sensor device such that respective ones of the three transducers exhibit different directional pick-up patterns with respect to direction of travel of sound waves in an ambient environment around the acoustic sensor device, such as dipole patterns that are orthogonal to one another in three-dimensional (3D) space. In other examples, other suitable numbers of transducers and/or other suitable directional pick-up patterns may be provided.

The term “about” is used herein in a manner to include deviations from a specified value that would be understood by one of ordinary skill in the art to effectively be the same as the specified value due to, for instance, the absence of appreciable, detectable, or otherwise effective difference in operation, outcome, characteristic, or other aspect of the disclosed methods and devices.

The present disclosure has been described with reference to specific examples that are intended to be illustrative only and not to be limiting of the disclosure. Changes, additions and/or deletions may be made to the examples without departing from the spirit and scope of the disclosure.

The foregoing description is given for clearness of understanding only, and no unnecessary limitations should be understood therefrom.

What is claimed is:

1. An acoustic sensor device, comprising:
a package;
a substrate disposed in the package or forming a part of the package;
a plurality of microelectromechanical system (MEMS) transducers supported by the substrate and packaged in the package; and
a plurality of sound ports configured to couple the plurality of MEMS transducers to an ambient environment of the acoustic sensor device, wherein the plurality of sound ports are arranged in the package such that respective MEMS transducers, among the plurality of MEMS transducers, exhibit different directional pick-up patterns with respect to sound waves traveling in the ambient environment of the acoustic sensor device.

2. The acoustic sensor device of claim 1, wherein the plurality of sound ports are arranged such that the plurality of MEMS transducers exhibit respective directional pick-up patterns that are orthogonal to each other.

3. The acoustic sensor device of claim 1, wherein the plurality of sound ports are arranged in the package such that the plurality of MEMS transducers exhibit respective dipole patterns that are orthogonal to each other.

4. The acoustic sensor device of claim 1, wherein at least one sound port, among the plurality of sound ports, comprises a mesh covering configured to cause at least one MEMS transducer, among the plurality of MEMS transducers, to exhibit a cardioid pick-up pattern with respect to sound waves traveling in the ambient environment of the acoustic sensor device.

5. The acoustic sensor device of claim 1, further comprising an application specific integrated circuit (ASIC) configured to read out and process respective electrical signals generated by respective MEMS transducers among the plurality of MEMS transducers.

6. The acoustic sensor device of claim 1, further comprising a lid attached to the substrate to encapsulate the plurality of MEMS transducers.

7. The acoustic sensor device of claim 1, wherein:
the plurality of MEMS transducers includes a first MEMS transducer and a second MEMS transducer, and
the plurality of sound ports includes
a first sound port configured to couple a first side of the first MEMS transducer to the ambient environment,
a second sound port configured to couple a first side of the second MEMS transducer to the ambient environment, and
a third sound port configured to couple a second side of the first MEMS transducer and a second side of the second MEMS transducer to the ambient environment.

8. The acoustic sensor device of claim 7, wherein:
the first sound port and the third sound port are arranged in-plane along a first axis on the substrate and spaced apart from each other along the first axis on the substrate; and
the second sound port and the third sound port are arranged in-plane along a second axis and spaced apart from each other along the second axis on the substrate.

9. The acoustic sensor device of claim 8, wherein the first axis and the second axis are orthogonal to each other.

10. The acoustic sensor device of claim 7, wherein the first sound port, the second sound port, and the third sound port are formed in the substrate of the package.

11. The acoustic sensor device of claim 7, wherein:
the first MEMS transducer comprises a first sensing element suspended over a first cavity, wherein the first MEMS transducer is arranged in the package such that the first cavity is placed over the first sound port formed in the substrate; and
the second MEMS transducer comprises a second sending element suspended over a second cavity, wherein the second MEMS transducer is arranged in the package such that the second cavity is placed over the second sound port formed in the substrate.

12. The acoustic sensor device of claim 7, wherein at least one of the first sound port and the second sound port includes a mesh covering.

13. The acoustic sensor device of claim 1, wherein a first sound port among the plurality of sound ports is configured to be coupled via an acoustic channel to a further sound port formed in an end product device configured to use the acoustic sensor device.

14. The acoustic sensor device of claim 13, wherein the acoustic channel is arranged such that a distance between the further sound port formed in the end product device and a second sound port among the plurality of sound ports of the acoustic sensor device is larger than a distance between the first sound port and the second sound port of the acoustic sensor device.

15. An acoustic sensor device, comprising:
a package;
a substrate disposed in the package or forming a part of the package;
a plurality of transducers formed in one or more semiconductor dies, the one or more semiconductor dies supported by the substrate and packaged in the package; and
a plurality of sound ports configured to couple the plurality of transducers to an ambient environment of the acoustic sensor device, wherein the plurality of sound ports are arranged in the package such that respective transducers, among the plurality of transducers, exhibit respective directional pick-up patterns that are orthogonal to each other.

16. The acoustic sensor device of claim 15, wherein the plurality of sound ports are arranged in the package such that the plurality of transducers exhibit respective dipole pick-up patterns that are orthogonal to each other.

17. The acoustic sensor device of claim 15, wherein the plurality of transducers comprise a plurality of microelectromechanical system (MEMS) transducers.

18. The acoustic sensor device of claim 15, further comprising an application specific integrated circuit (ASIC) configured to read out and process respective electrical signals generated by respective transducers among the plurality of transducers.

19. The acoustic sensor device of claim 15, further comprising a lid attached to the substrate to encapsulate the plurality of transducers.

20. The acoustic sensor device of claim 15, wherein a particular sound port among the plurality of sound ports is shared by multiple transducers among the plurality of transducers such that the particular sound ports couples the multiple transducers to the ambient environment.
